(19) United States
(12) Patent Application Publication
(10) Pub. No.: US 2017/0191187 A1
(43) Pub. Date: Jul. 6, 2017

(54) SINGLE CRYSTAL METAL FILM CONTAINING HYDROGEN ATOMS OR HYDROGEN IONS AND METHOD FOR MANUFACTURING SAME

(71) Applicant: IUDF-HYU (INDUSTRY-UNIVERSITY COOPERATION FOUNDATION HANYANG UNIVERSITY), Seoul (KR)

(72) Inventors: Ho Bum PARK, Seoul (KR); Min Yong LEE, Goyang-si (KR); Sunmi PARK, Bucheon-si (KR); Hee Wook YOON, Gwacheon-si (KR); Hansu KIM, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 15/317,590

(22) PCT Filed: Jun. 3, 2015
(86) PCT No.: PCT/KR2015/005552

§ 371 Date: Feb. 13, 2017

(30) Foreign Application Priority Data
Jun. 9, 2014 (KR) 10-2014-0069286
Jun. 1, 2015 (KR) 10-2015-0077600

(51) Int. Cl. C30B 29/02; H01M 4/62; H01L 27/12; C30B 1/04; H01L 29/45; H01L 31/02; H01M 10/0525; H01M 4/86

(52) U.S. Cl. CPC C30B 29/02; H01M 10/0525; H01M 4/625; H01M 4/8673; C30B 1/04; H01L 29/456; H01L 31/02008; H01L 27/124

(57) ABSTRACT

The present disclosure relates to a single crystal metal film containing hydrogen atoms or hydrogen ions, which is oriented only in the (111) crystal plane on a substrate or without a substrate, and a method for preparing the same.

According to the present disclosure, a single crystal metal film containing hydrogen atoms or hydrogen ions, which is oriented only in the (111) crystal plane, can be formed in various shapes such as a foil, a plate, a block or a tube even without an expensive substrate only by heat-treating a metal precursor having crystallinity and preference for orientation in the crystal plane under a hydrogen atmosphere. Because electrical conductivity is improved due to the contained hydrogen atoms or hydrogen ions, the single crystal metal film can be used as a material for a display driver IC, a semiconductor device, a lithium secondary battery, a fuel cell, a solar cell or a gas sensor.

### TECHNICAL FIELD

The present disclosure relates to a single crystal metal film containing hydrogen atoms or hydrogen ions and a method for preparing the same, more particularly to a single crystal metal film containing hydrogen atoms or hydrogen ions, which is oriented only in the (111) crystal plane on a substrate or without a substrate, and a method for preparing the same.

### BACKGROUND ART

Recently, demands on the technology for epitaxial growth of a metal film on an insulator or semiconductor substrate for application in electric and electronic industries are increasing consistently.

In general, in heat treatment for recrystallization and growth of metal particles, the grain growth rate does not increase consistently and reaches saturation even if the heat treatment temperature and time are increased due to inter-particle stress. Although a single crystal copper substrate having an epitaxially grown (111) crystal plane can be prepared through common sputtering or evaporation and subsequent heat treatment, an expensive substrate (underlayer) such as magnesium oxide (MgO) or sapphire (111) single crystal is necessary for epitaxial growth of a single crystal copper (Cu) film having the (111) crystal plane.

To review some references regarding the technology of preparing the single crystal metal film, a method of crystallizing a metal thin film layer (Cu) by performing heat treatment while injecting a hydrogen/argon mixture gas to the metal thin film layer (Cu) on a substrate under the condition of 800-1000° C. and 1-760 torr has been disclosed (patent document 1). However, the metal thin film layer is formed on a substrate such as a silicon wafer and does not have a single crystal structure oriented only in the (111) crystal plane.

Meanwhile, a method of obtaining a single crystal copper thin film oriented in the (111) crystal plane on a MgO substrate by using platinum as a buffer layer has been disclosed (non-patent document 1). However, there are problems that the expensive MgO substrate is used and a complicated process of interposing the buffer layer such as platinum is necessary.

Also, a method of growing a single crystal copper film with a thickness of 100 nm on a MgO substrate by ultra-high vacuum magnetron sputtering deposition is known (non-patent document 2). But, it also has the problems that the expensive MgO substrate is used and the metal film has various crystal planes in addition to the (111) crystal plane.

In addition, a method of growing a single crystal nickel film oriented in the (111) crystal plane with a thickness of 170 nm on a sapphire substrate by ultra-high vacuum laser ablation deposition is known. However, commercialization does not seem easy because it also uses the expensive sapphire substrate and a complicated process of ultra-high vacuum laser ablation deposition is necessary (non-patent document 3).

The inventors of the present disclosure have researched on a method for forming a single crystal metal film without an expensive substrate. As a result, they have completed the present disclosure based on the finding that a single crystal metal film containing hydrogen atoms or hydrogen ions, which is oriented only in the (111) crystal plane regardless of the crystallinity of a metal precursor and the orientation of the crystal plane, only by optimizing the heat treatment condition of a metal precursor of a specific thickness using, e.g., hydrogen.

### REFERENCES OF RELATED ART

### Patent Documents

Patent document 1: Korean Patent Registration No. 10-1132706.

### Non-Patent Documents

Non-patent document 1: T. Mewes et al., Surface Science 481, 87-96 (2001).
Non-patent document 2: J. M. Purswani et al., Thin Solid Films 515, 1166-1170 (2006).
Non-patent document 3: I. V. Malikov et al., Thin Solid Films 519, 527-535 (2010).

### DISCLOSURE

### Technical Problem

The present disclosure is directed to providing a single crystal metal film containing hydrogen atoms or hydrogen ions, which is oriented only in the (111) crystal plane and has improved electrical conductivity, and a method for preparing the same through a heat treatment process only.

### Technical Solution

The present disclosure provides a single crystal metal film containing hydrogen atoms or hydrogen ions, which is oriented only in the (111) crystal plane on a substrate or without a substrate.

The substrate may be a single crystal substrate or a non-single crystal substrate.

The substrate may be a silicon-based substrate, a metal oxide-based substrate or a ceramic substrate.

The substrate may be selected from a group consisting of silicon (Si), silicon dioxide (SiO₂), silicon nitride (Si₃N₄), zinc oxide (ZnO), zirconium dioxide (ZrO₂), nickel oxide (NiO), hafnium oxide (HfO₂), cobalt(II) oxide (CoO), copper(II) oxide (CuO), iron(II) oxide (FeO), magnesium oxide (MgO), α-aluminum oxide (α-Al₂O₃), aluminum oxide (Al₂O₃), strontium titanate (SrTiO₃), lanthanum aluminate (LaAlO₃), titanium dioxide (TiO₂), tantalum dioxide (TaO₂), niobium dioxide (NbO₂) and boron nitride (BN).

The single crystal metal film containing hydrogen atoms or hydrogen ions may be selected from a group consisting of copper (Cu), nickel (Ni), cobalt (Co), iron (Fe), ruthenium (Ru), platinum (Pt), palladium (Pd), gold (Au), silver (Ag), aluminum (Al), chromium (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir) and zirconium (Zr).

The single crystal metal film containing hydrogen atoms or hydrogen ions may be in the form of a foil, a plate, a block or a tube.

The present disclosure also provides a method for preparing a single crystal metal film containing hydrogen atoms or hydrogen ions, which includes:

i) a step of preparing a metal precursor which is non-crystalline, polycrystalline with preferred orientation or single crystalline other than in the (111) crystal plane;

ii) a step of forming a single crystal metal film oriented only in the (111) crystal plane by heat-treating the metal precursor of the step i) under a hydrogen atmosphere; and

iii) a step of cooling the single crystal metal film oriented only in the (111) crystal plane of the step ii).

The metal precursor of the step i) may be selected from a group consisting of copper (Cu), nickel (Ni), cobalt (Co), iron (Fe), ruthenium (Ru), platinum (Pt), palladium (Pd), gold (Au), silver (Ag), aluminum (Al), chromium (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir) and zirconium (Zr). The metal precursor of the step i) may be in the form of a foil, a plate, a block or a tube.

The metal precursor of the step i) may be a commercially available copper foil.

The commercially available copper foil may have a thickness of 1-20 μm.

The maximum size of copper particles present in the commercially available copper foil having a specific thickness within the range of 1-20 μm may exceed the specific thickness.

Physical deformation may be applied to the commercially available copper foil having a thickness of 1-20 μm.

The hydrogen atmosphere of the step ii) may be created by injecting 10-1,000 sccm of hydrogen or 10-1,000 sccm of hydrogen and 10-1,000 sccm of argon.

The heat treatment of the step ii) may be performed at 900-1,600° C. and 1 mtorr to 300,000 torr for 1-10 hours.

The cooling of the step iii) may be performed slowly at a cooling rate of 10-50° C./min.

The cooling of the step iii) may be performed while injecting 10-1,000 sccm of hydrogen.

The present disclosure also provides a display driver IC containing the single crystal metal film containing hydrogen atoms or hydrogen ions.

The present disclosure also provides a semiconductor device containing the single crystal metal film containing hydrogen atoms or hydrogen ions.

The present disclosure also provides a lithium secondary battery containing the single crystal metal film containing hydrogen atoms or hydrogen ions.

The present disclosure also provides a fuel cell containing the single crystal metal film containing hydrogen atoms or hydrogen ions.

The present disclosure also provides a solar cell containing the single crystal metal film containing hydrogen atoms or hydrogen ions.

The present disclosure also provides a gas sensor containing the single crystal metal film containing hydrogen atoms or hydrogen ions.

### Advantageous Effects

According to the present disclosure, a single crystal metal film containing hydrogen atoms or hydrogen ions, which is oriented only in the (111) crystal plane, can be formed in various shapes such as a foil, a plate, a block or a tube even without an expensive substrate only simply by heat-treating a metal precursor having crystallinity and preference for orientation in the crystal plane. Because electrical conductivity is improved due to the contained hydrogen atoms or hydrogen ions, the single crystal metal film can be used as a material for a display driver IC, a semiconductor device, a lithium secondary battery, a fuel cell, a solar cell or a gas sensor.

### BRIEF DESCRIPTION OF DRAWINGS

FIGS. 1 (a) and (b) respectively show the X-ray diffraction (XRD) pattern and electron backscatter diffraction (EBSD) map (111) of a single crystal copper film epitaxially grown on an existing single crystal MgO (111) substrate in the same direction.

FIGS. 2 (a) and (b) respectively show the X-ray diffraction (XRD) pattern and electron backscatter diffraction (EBSD) map (200) of a single crystal copper film epitaxially grown on an existing single crystal MgO (200) substrate in the same direction.

FIGS. 3 (a) and (b) respectively show the scanning electron microscopic (SEM) image of an existing copper foil with dominant orientation after heat treatment and the X-ray diffraction (XRD) pattern showing crystal growth direction before/after heat treatment.

FIG. 4 shows a TOF-SIMS result of the surface of copper films heat-treated in Examples 1-2 and Comparative Example 1.

FIGS. 5 (a) and (b) respectively show the scanning electron microscopic (SEM) image and X-ray diffraction (XRD) pattern of a commercially available copper foil of Example 1.

FIGS. 6 (a) and (b) respectively show the scanning electron microscopic (SEM) image and X-ray diffraction (XRD) pattern of a copper film heat-treated in Example 1.

FIGS. 7 (a) and (b) respectively show the scanning electron microscopic (SEM) image and X-ray diffraction (XRD) pattern of a copper film heat-treated in Comparative Example 1.

FIGS. 8 (a) and (b) respectively show the electron backscatter diffraction (EBSD) pattern of copper films heat-treated in Example 1 and Comparative Example

FIG. 9 shows the change in electrical conductivity of a copper film heat-treated in Example 1 and the change in electrical conductivity of copper films prepared in Comparative Examples 1-2.

### BEST MODE

Hereinafter, a single crystal metal film containing hydrogen atoms or hydrogen ions, which is oriented only in the (111) crystal plane on a substrate or without a substrate, and a method for preparing the same are described in detail referring to the attached drawings.

In general, if a metal film is formed on an amorphous or non-crystalline substrate such as a silicon oxide film (SiO₂), the metal film has a polycrystalline structure. A metal film formed by heat-treating a metal foil or sheet such as copper, nickel, cobalt, etc. without a substrate also has grains and grain boundaries because the metal foil or sheet itself is polycrystalline.

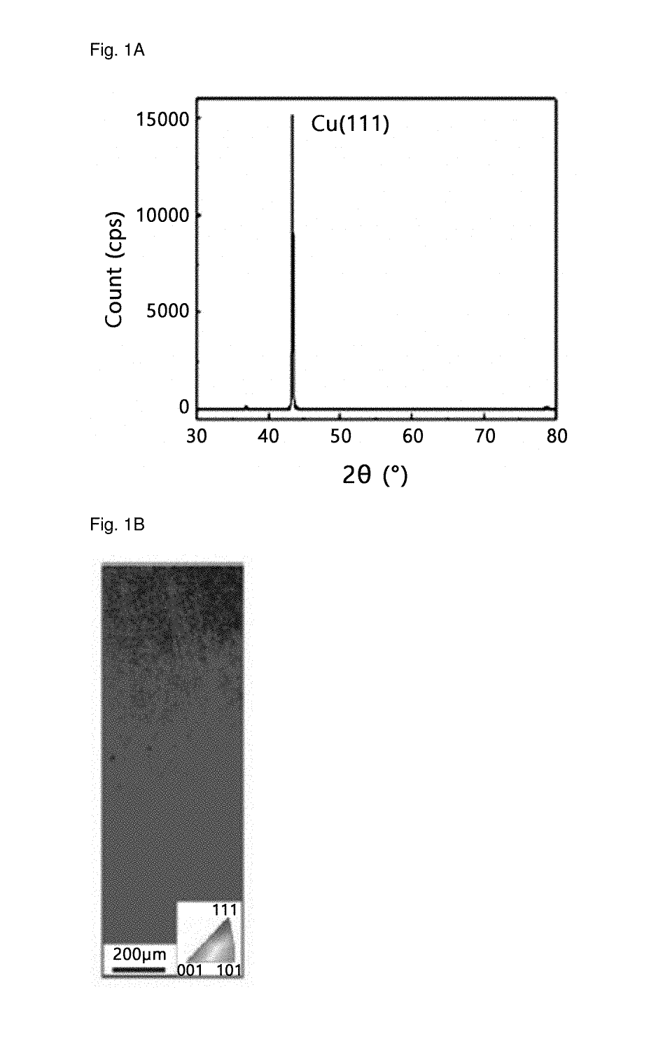

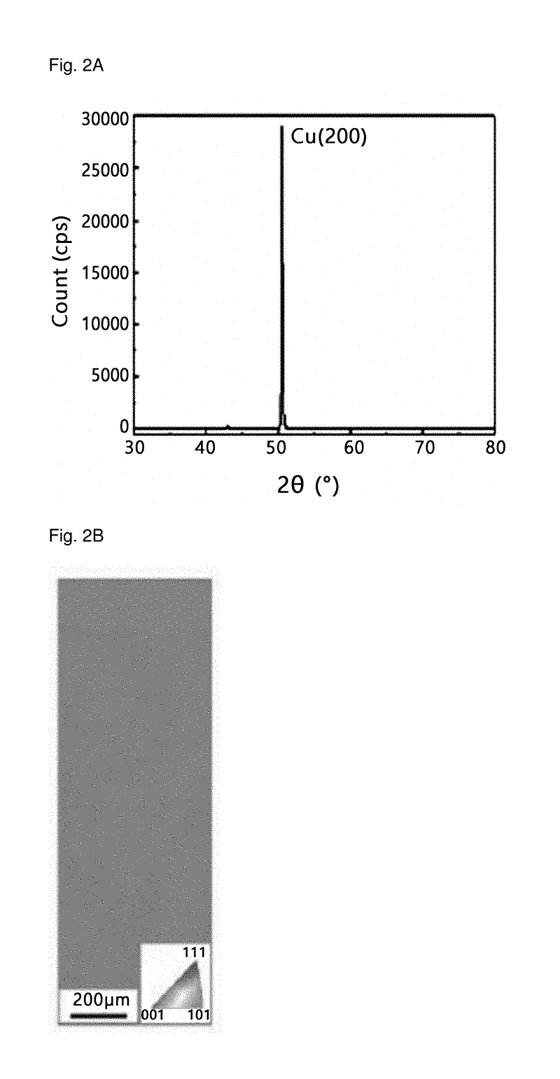

As seen from FIGS. 1 and 2, a copper film epitaxially grown on an existing single crystal (111) magnesium oxide (MgO) or (200) magnesium oxide substrate may form a (111) single crystal or (200) single crystal copper film with no grain boundary. However, for the epitaxial growth of the single crystal copper film having a (111) or (200) crystal plane, an expensive single crystal (111) or (200) magnesium oxide (MgO) sapphire substrate (underlayer) is necessary.

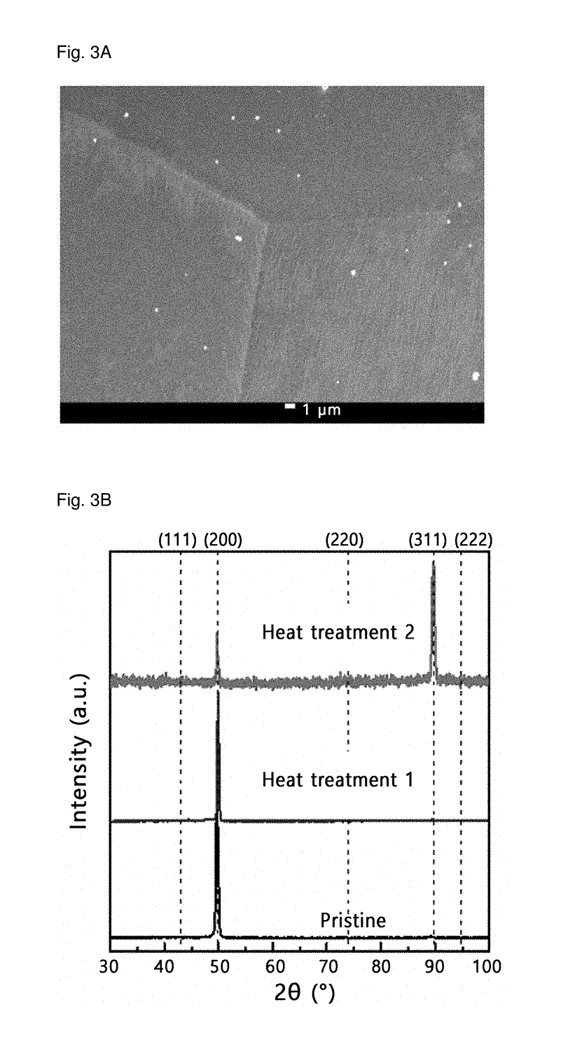

Also, as seen from FIG. 3, although grain growth can occur through heat treatment of an existing copper foil having dominant orientation, the resulting film is polycrystalline with various crystal planes.

In order to solve this problem, the present disclosure provides a method for forming a single crystal metal film oriented only in the (111) crystal plane through a specific heat treatment process of a polycrystalline metal foil with preferred orientation in the crystal plane without an expensive substrate for growth of a single crystal having the copper (111) crystal plane.

That is to say, the present disclosure provides a single crystal metal film containing hydrogen atoms or hydrogen ions, which is oriented only in the (111) crystal plane on a substrate or without a substrate, by performing heat treatment under a hydrogen atmosphere.

Although the present disclosure is advantageous in that a single crystal metal film containing hydrogen atoms or hydrogen ions can be formed without an expensive single crystal substrate such as magnesium oxide or sapphire, the single crystal metal film can also be formed using a single crystal substrate or a non-single crystal substrate.

When a single crystal substrate or a non-single crystal substrate is used, the substrate may be a silicon-based substrate, a metal oxide-based substrate or a ceramic substrate. For example, one selected from a group consisting of silicon (Si), silicon dioxide (SiO₂), silicon nitride (Si₃N₄), zinc oxide (ZnO), zirconium dioxide (ZrO₂), nickel oxide (NiO), hafnium oxide (HfO₂), cobalt(II) oxide (CoO), copper(II) oxide (CuO), iron(II) oxide (FeO), magnesium oxide (MgO), α-aluminum oxide (α-Al₂O₃), aluminum oxide (Al₂O₃), strontium titanate (SrTiO₃), lanthanum aluminate (LaAlO₃), titanium dioxide (TiO₂), tantalum dioxide (TaO₂), niobium dioxide (NbO₂) and boron nitride (BN) may be used, although not being limited thereto.

The single crystal metal film containing hydrogen atoms or hydrogen ions, which is oriented only in the (111) crystal plane, of the present disclosure may be selected from a group consisting of copper (Cu), nickel (Ni), cobalt (Co), iron (Fe), ruthenium (Ru), platinum (Pt), palladium (Pd), gold (Au), silver (Ag), aluminum (Al), chromium (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir) and zirconium (Zr), more specifically copper (Cu), although not being limited thereto.

The single crystal metal film containing hydrogen atoms or hydrogen ions, which is oriented only in the (111) crystal plane, of the present disclosure may be in any form, including a foil, a plate, a block or a tube. Specifically, it may be in the form of a foil.

The present disclosure also provides a method for preparing a single crystal metal film containing hydrogen atoms or hydrogen ions, which includes:

i) a step of preparing a metal precursor which is non-crystalline, polycrystalline with preferred orientation or single crystalline other than in the (111) crystal plane;

ii) a step of forming a single crystal metal film oriented only in the (111) crystal plane by heat-treating the metal precursor of the step i) under a hydrogen atmosphere; and

iii) a step of cooling the single crystal metal film oriented only in the (111) crystal plane of the step ii).

First, in the present disclosure, a single crystal metal precursor which is non-crystalline, polycrystalline with preferred orientation or single crystalline other than in the (111) crystal plane is prepared as a metal precursor for forming a single crystal metal film. Because the present disclosure provides a single crystal metal film by maximizing the grain growth of single crystals in the (111) crystal plane through recrystallization and abnormal grain growth only by heat-treating the metal precursor having crystallinity and preferred orientation in the crystal plane, metal precursors of various crystal structures may be used as starting materials.

The metal precursor may be selected from a group consisting of copper (Cu), nickel (Ni), cobalt (Co), iron (Fe), ruthenium (Ru), platinum (Pt), palladium (Pd), gold (Au), silver (Ag), aluminum (Al), chromium (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir) and zirconium (Zr). In addition, the metal precursor may be in any form including a foil, a plate, a block or a tube. Specifically, a foil may be used to form a uniform single crystal metal film through heat treatment. More specifically, a commercially available copper foil which is readily available and inexpensive may be used.

In the present disclosure, the thickness of the metal precursor is another important factor in forming the single crystal metal film oriented only in the (111) crystal plane. In particular, when the metal precursor is in the form of a foil, specifically a commercially available copper foil, the thickness affects the solid solubility of carbon during recrystallization following the heat treatment. In this regard, the commercially available copper foil according to the present disclosure may have a thickness of 1-20 μm. When the thickness of the commercially available copper foil is smaller than 1 μm, recrystallization may not occur because the heat treatment cannot be performed properly. And, when it exceeds 20 μm, a single crystal metal film oriented only in the (111) crystal plane cannot be obtained even if the heat treatment is performed under the same condition. In this case, a metal film having various crystal plane directions as the commercially available copper foil or having a crystal structure with dominant orientation in the (100) crystal plane is obtained.

In the commercially available copper foil having a thickness of 1-20 μm, copper particles of various sizes are mixed. Specifically, when the maximum size of the copper particles present in the commercially available copper foil having a specific thickness exceeds the specific thickness, a uniform single crystal copper film containing hydrogen atoms or hydrogen ions, which is oriented only in the (111) crystal plane, may be obtained.

In addition, by applying physical deformation such as elongation, etc. to the commercially available copper foil having a thickness of 1-20 μm, hydrogen atoms or hydrogen ions may be more effectively contained in the copper film.

Next, in the step ii), a single crystal metal film oriented only in the (111) crystal plane is formed by heat-treating the metal precursor of various crystal structures prepared in the step i) under a hydrogen atmosphere.

The heat treatment in the step ii) is performed at 900-1,600° C. and 1 mtorr to 30000 torr for 1-10 hours under a hydrogen atmosphere in order to prevent oxidation of the metal film and improve electrical conductivity by containing hydrogen atoms or hydrogen ions in the metal film. Specifically, the hydrogen atmosphere may be created by injecting 10-1,000 sccm of hydrogen or 10-1,000 sccm of hydrogen and 10-1,000 sccm of argon.

In particular, for a copper foil, although grain growth can occur more distinctly as the heat treatment temperature approaches the melting point of about 1,083° C. due to increased thermal energy, surface roughness becomes poor due to severe sublimation of copper atoms on the foil surface. At a lower temperature, recrystallization to the thermodynamically most stable (111) crystal plane occurs in the bulk of the foil. The foil has a thickness smaller than a specific thickness so that grain growth can occur. It is because less thermal energy is required for the bulk of the foil to reach the thermodynamically stable state. In addition, softening is possible at low temperature due to thermally activated diffusion of metal atoms.

In addition, during the heat treatment under a hydrogen atmosphere, the content of hydrogen atoms or hydrogen ions increases and the migration of copper atoms is accelerated as penetration and sorption of hydrogen molecules occur on the copper surface. This leads to decreased melting point and the surface reaches a semi-melting state where copper particles are rearranged in the same direction as that of bulk particles. Meanwhile, for a foil having preferred orientation through a cold rolling process, etc., the recrystallization and grain growth can be maximized by reducing the energy barrier to a stabilized state as compared to a foil having various orientations in crystal planes.

If the parameters of the heat treatment process, i.e., temperature, pressure, time and injection rate of hydrogen or a mixture gas of hydrogen and argon, are outside the above-described ranges, a single crystal metal film oriented only in the (111) crystal plane is not formed. Accordingly, in the present disclosure, a single crystal metal film oriented only in the (111) crystal plane can be formed by crystallizing the metal precursor by controlling the process parameters for the heat treatment in the step ii) within the above-described ranges.

Therefore, the present disclosure is fundamentally distinguished from the methods of forming a single crystal metal thin film on a single crystal substrate or forming a polycrystalline metal film by heat-treating a metal precursor without using a substrate. Indeed, whereas a single crystal copper film was formed using a copper foil precursor with a size of 1 cm×1 cm at most by the existing method, the present disclosure allows for commercialization through large-scale production because a single crystal metal film containing hydrogen atoms or hydrogen ions can be prepared by heat-treating a metal precursor of any size under a hydrogen atmosphere.

Finally, the single crystal metal film containing hydrogen atoms or hydrogen ions, which is oriented only in the (111) crystal plane, desired by the present disclosure can be prepared by cooling the single crystal metal film oriented only in the (111) crystal plane of the step ii). Specifically, the cooling may be performed slowly at a cooling rate of 10-50° C./min. In particular, when the cooling is performed faster than the above-described cooling rate, cracking may occur as the metal film is grown and arranged. Also, the cooling may be performed while injecting 10-1,000 sccm of hydrogen in order to avoid an oxidation atmosphere that may be produced during the cooling process.

The present disclosure also provides a display driver IC, a semiconductor device, a lithium secondary battery, a fuel cell, a solar cell, a gas sensor, etc. including the single crystal metal film containing hydrogen atoms or hydrogen ions, which is oriented only in the (111) crystal plane, prepared according to the present disclosure.

### MODE FOR INVENTION

Hereinafter, specific examples are described in detail.

### Examples: Preparation of Single Crystal Copper Films Containing Hydrogen Atoms or Hydrogen Ions

After putting a copper foil (99.9%, Alfa Aesar, USA) with a thickness of 10 μm and a size of 10 cm×10 cm in length and breadth, as a metal precursor, in a chamber, a copper film was formed by heat-treating at 1,005° C. and 500 torr for 2 hours while injecting 100 sccm of hydrogen. A single crystal copper film containing hydrogen atoms or hydrogen ions was prepared by cooling the formed copper film at a rate of 10° C./min.

The parameters for the heat treatment processes in Examples 1-2 and Comparative Examples 1-2 are described in Table 1.

TABLE 1

| | Thick- | Temper- | | | Hydrogen |
|---|---|---|---|---|---|
| | ness | ature | Pressure | Time | atmosphere |
| Examples | (μm) | (° C.) | (torr) | (hr) | (hydrogen, sccm) |
| Example 1 | 10 | 1,005 | 500 | 2 | 100 |
| Example 2 | 10 | 1,005 | 500 | 2 | 50 |
| Comparative | 18 | 850 | 500 | 0.5 | None |
| Example 1 | | | | | |
| Comparative | 75 | 1,005 | 500 | 2 | 100 |
| Example 2 | | | | | |

* Copper foil size = 10 cm × 10 cm (length × breadth).
* Cooling rate = 10° C./min.

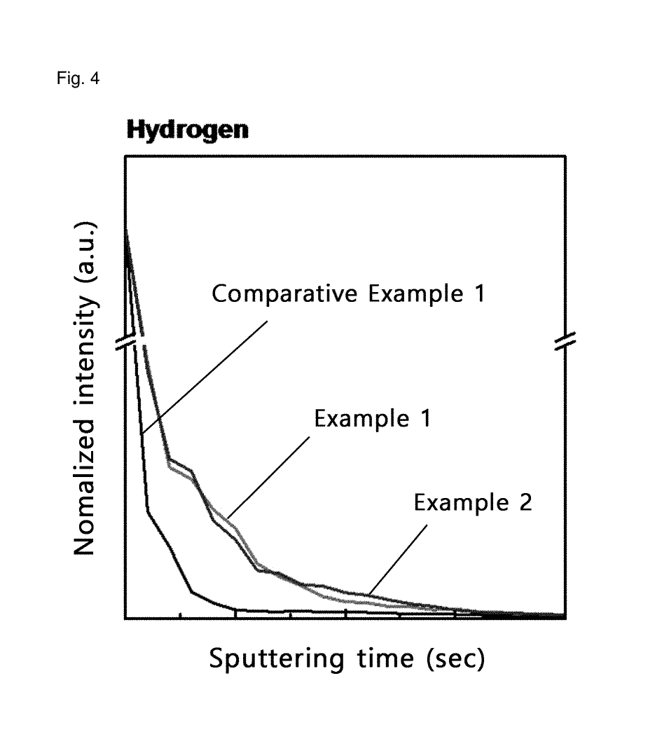

FIG. 4 shows a time-of-flight secondary ion mass spectroscopy (TOF-SIMS) result of the surface of the copper films heat-treated in Examples 1-2 and Comparative Example 1. As seen from FIG. 4, the copper films of Examples 1-2 according to the present disclosure contain hydrogens atom or hydrogen ions on the copper film surface.

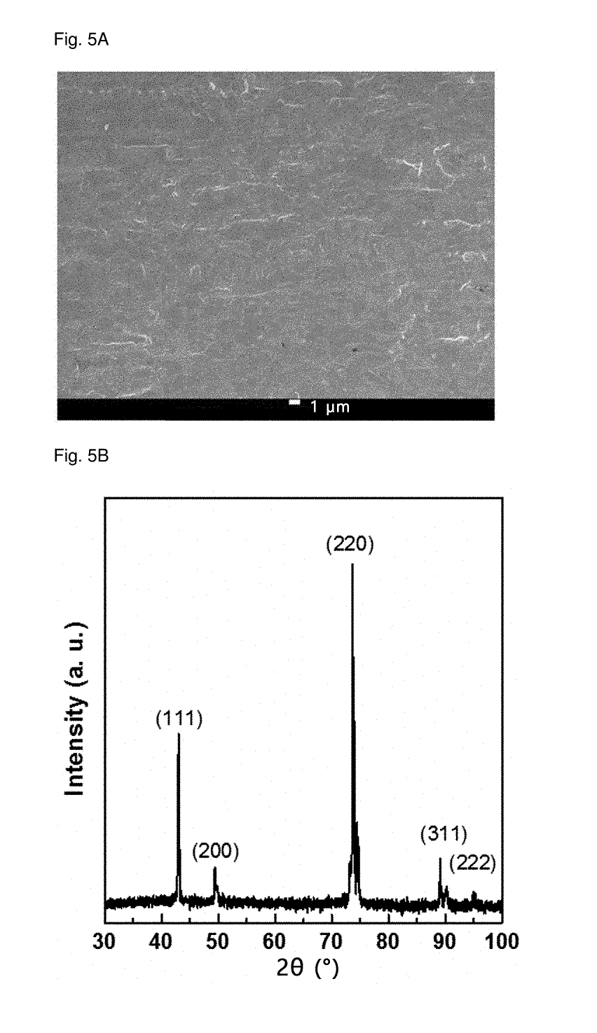

FIGS. 5 (a) and (b) respectively show the scanning electron microscopic (SEM) image and X-ray diffraction (XRD) pattern of the commercially available copper foil of Example 1 according to the present disclosure. The presence of grains and grain boundaries is confirmed from the scanning electron microscopic (SEM) image of FIG. 5 (a). And, the X-ray diffraction pattern of FIG. 5 (b) shows that the copper foil is polycrystalline with orientations in various crystal planes.

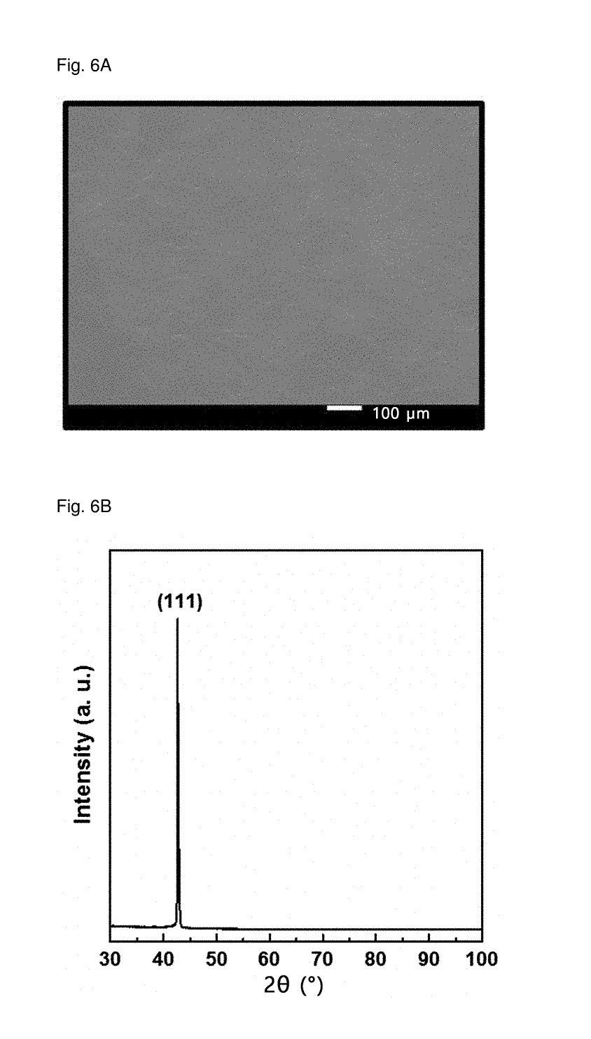

FIGS. 6 (a) and (b) respectively show the scanning electron microscopic (SEM) image and X-ray diffraction (XRD) pattern of the copper film heat-treated in Example 1 according to the present disclosure. It can be seen that copper film has no grain boundary. The X-ray diffraction pattern shows that a single crystal copper film oriented only in the (111) crystal plane has been formed through recrystallization by the heat treatment.

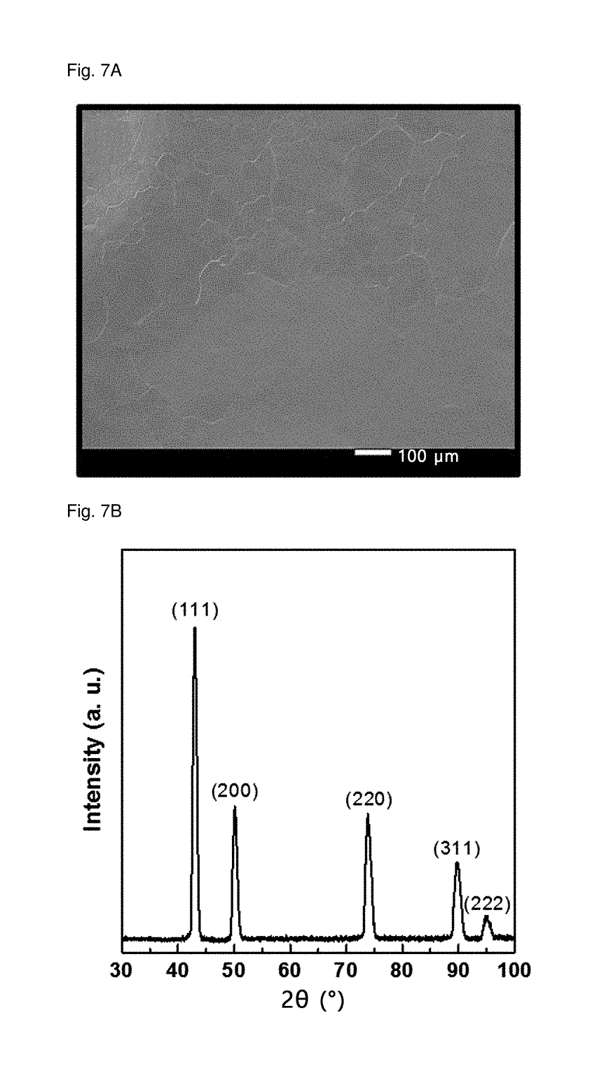

FIGS. 7 (a) and (b) respectively show the scanning electron microscopic (SEM) image and X-ray diffraction (XRD) pattern of the copper film heat-treated in Comparative Example 1. It can be seen that copper grains and grain boundaries are present and the copper film foil is polycrystalline with orientations in various crystal planes.

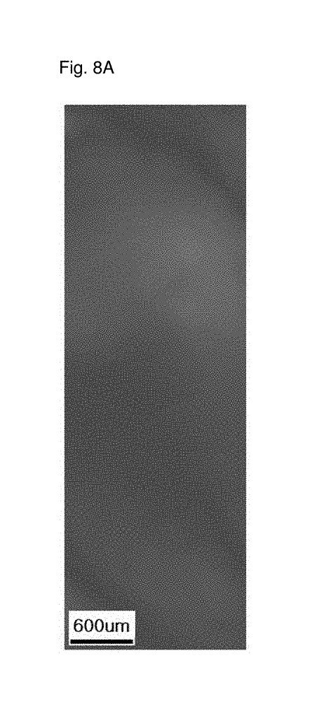

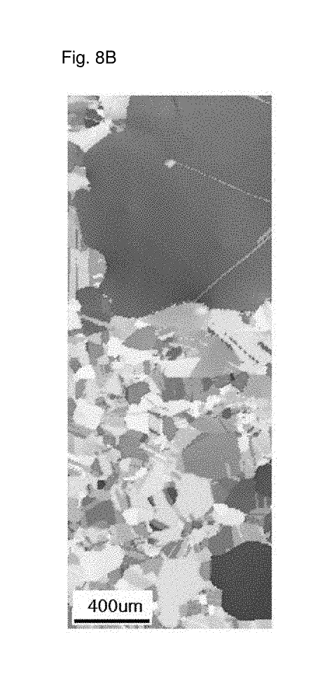

FIGS. 8 (a) and (b) respectively show the electron backscatter diffraction (EBSD) pattern of copper films heat-treated in Example 1 according to the present disclosure and Comparative Example 1 for further analysis of the crystal plane orientations. From FIG. 8 (a), it can be seen that there is no grain boundary or defect in the whole area and the single crystal copper film oriented only in the (111) plane has been formed. In contrast, grain boundaries and defects are observed in FIG. 8 (b).

When a copper foil with a thickness of 75 μm was used as a metal precursor as in Comparative Example 2, copper grains and grain boundaries were present in the copper film even when heat treatment was performed under the same condition as Example 1 (not shown). Through heat treatment experiments for copper foils with various thicknesses, it was found out that a single crystal copper film cannot be obtained if the thickness of the copper foil exceeds 20 μm.

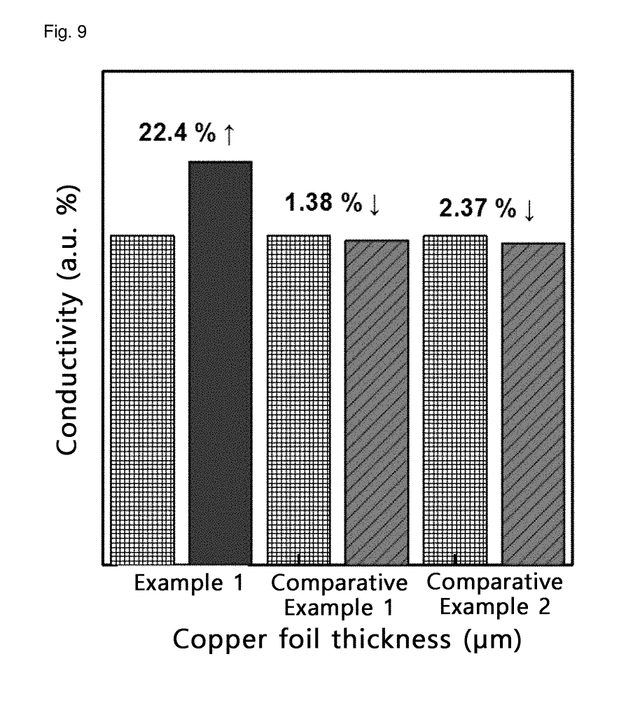

FIG. 9 shows the change in electrical conductivity of the single crystal copper film containing hydrogen atoms or hydrogen ions prepared in Example 1 according to the present disclosure and the change in electrical conductivity of the copper films prepared in Comparative Examples 1-2. As seen from FIG. 9, the single crystal copper film containing hydrogen atoms or hydrogen ions prepared in Example 1 according to the present disclosure exhibits greatly increased electrical conductivity, improved by about 22.4%. This is because of the hydrogens atom or hydrogen ions contained in the single crystal copper film due to the heat treatment process performed under a hydrogen atmosphere. Accordingly, it was demonstrated that the single crystal metal film formed through the heat treatment process of the present disclosure contains hydrogens atom or hydrogen ions.

### INDUSTRIAL APPLICABILITY

According to the present disclosure, a single crystal metal film containing hydrogen atoms or hydrogen ions, which is oriented only in the (111) crystal plane, can be formed in various shapes such as a foil, a plate, a block or a tube even without an expensive substrate only by heat-treating a metal precursor having crystallinity and preference for orientation in the crystal plane under a hydrogen atmosphere. Because electrical conductivity is improved due to the contained hydrogen atoms or hydrogen ions, the single crystal metal film can be used as a material for a display driver IC, a semiconductor device, a lithium secondary battery, a fuel cell, a solar cell or a gas sensor.

1. A single crystal metal film comprising hydrogen atoms or hydrogen ions, which is oriented only in the (111) crystal plane on a substrate or without a substrate.

2. The single crystal metal film comprising hydrogen atoms or hydrogen ions according to claim 1, wherein the substrate is a single crystal substrate or a non-single crystal substrate.

3. The single crystal metal film comprising hydrogen atoms or hydrogen ions according to claim 1, wherein the substrate is a silicon-based substrate, a metal oxide-based substrate or a ceramic substrate.

4. The single crystal metal film comprising hydrogen atoms or hydrogen ions according to claim 3, wherein the substrate is selected from a group consisting of silicon (Si), silicon dioxide (SiO₂), silicon nitride (Si₃N₄), zinc oxide (ZnO), zirconium dioxide (ZrO₂), nickel oxide (NiO), hafnium oxide (HfO₂), cobalt(II) oxide (CoO), copper(II) oxide (CuO), iron(II) oxide (FeO), magnesium oxide (MgO), α-aluminum oxide (α-Al₂O₃), aluminum oxide (Al₂O₃), strontium titanate (SrTiO₃), lanthanum aluminate (LaAlO₃), titanium dioxide (TiO₂), tantalum dioxide (TaO₂), niobium dioxide (NbO₂) and boron nitride (BN).

5. The single crystal metal film comprising hydrogen atoms or hydrogen ions according to claim 1, wherein the single crystal metal film comprising hydrogen atoms or hydrogen ions is selected from a group consisting of copper (Cu), nickel (Ni), cobalt (Co), iron (Fe), ruthenium (Ru), platinum (Pt), palladium (Pd), gold (Au), silver (Ag), aluminum (Al), chromium (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir) and zirconium (Zr).

6. The single crystal metal film comprising hydrogen atoms or hydrogen ions according to claim 1, wherein the single crystal metal film comprising hydrogen atoms or hydrogen ions is in the form of a foil, a plate, a block or a tube.

7.-17. (canceled)

18. A display driver IC comprising the single crystal metal film comprising hydrogen atoms or hydrogen ions according to claim 1.

19. A semiconductor device comprising the single crystal metal film comprising hydrogen atoms or hydrogen ions according to claim 1.

20. A lithium secondary battery comprising the single crystal metal film comprising hydrogen atoms or hydrogen ions according to claim 1.

21. A fuel cell comprising the single crystal metal film comprising hydrogen atoms or hydrogen ions according to claim 1.

22. A solar cell comprising the single crystal metal film comprising hydrogen atoms or hydrogen ions according to claim 1.

23. A gas sensor comprising the single crystal metal film comprising hydrogen atoms or hydrogen ions according to claim 1.
